(19) United States
(12) Patent Application Publication
(10) Pub. No.: US 2005/0090047 A1
(43) Pub. Date: Apr. 28, 2005

(54) Method of making a MOS transistor having improved total radiation-induced leakage current

(75) Inventors: Frank W. Hawley, Campbell, CA (US); Daniel Wang, San Jose, CA (US)

Correspondence Address: SIERRA PATENT GROUP, LTD., P O BOX 6149, STATELINE, NV, 89449, US

(73) Assignee: Actel Corporation, a California Corporation.

(21) Appl. No.: 10/929,106

(22) Filed: Aug. 27, 2004

Related U.S. Application Data
(63) Continuation-in-part of application No. 10/036,303, filed on Dec. 28, 2001, now abandoned.
Application No. 10/036,303 is a division of application No. 09/741,949, filed on Dec. 20, 2000, now abandoned.

(51) Int. Cl. H01L 21/336; H01L 21/8234; H01L 21/76

(52) U.S. Cl. 438/197; 438/424; 438/296

(57) ABSTRACT

A method for fabricating a shallow-trench isolation transistor an a semi-conductor substrate includes forming a single isolation trench having a uniform cross section to define an active region in the silicon substrate. The method includes performing sidewall isolation implants on the side and bottom walls of said isolation trench. The method includes depositing a dielectric isolation material in said isolation trench. The method includes planarizing the top surface of said silicon substrate and said dielectric isolation material. The method includes forming a gate oxide layer over said active region in said silicon substrate. The method includes forming and defining gate regions over said oxide layer in said active region in said silicon substrate. The method includes forming source and drain regions in the active region in the silicon substrate.

### CROSS REFERENCED APPLICATIONS

This application is a continuation-in part of co-pending U.S. patent application Ser. No. 10/036,303, filed Dec. 28, 2001, which is a divisional of U.S. patent application Ser. No. 09/741,949, filed Dec. 20, 2000, now abandoned.

### BACKGROUND

1. Field of the Invention

The present invention relates to MOS transistors. More particularly, the present invention relates to MOS transistors having improved total radiation-induced leakage currents.

2. The Prior Art

It is known that MOS transistors exhibit increased radiation-induced leakage along channel ends at the birds beak region of the field oxide edges caused by electron-hole pair charge buildup. This effect is only seen in n-channel devices. P-channel devices are not negatively affected. It is known to reduce this radiation-induced current leakage by increasing the boron field channel-stop implant dose under the birds beak edges of the field oxide isolation regions. Typically, field channel-stop implant doses may be increased from about 6e13 up to about 1.2e14.

While increasing the field channel-stop implant dose is known to decrease this radiation-induced current leakage, the increased field channel-stop implant dose has the unwanted effect of decreasing the junction breakdown voltage of the MOS transistor. The need to avoid unwanted lowering of the junction breakdown of the transistor limits the use of increased field channel-stop implant dose as a means of decreasing the radiation-induced current leakage in MOS transistors.

Recently, shallow-trench isolation has been used as an isolation technique. Use of this technique, in which trenches are etched in the silicon substrate and filled with deposited silicon dioxide, provides a deep isolation and a much more planarized surface than can be obtained by using the traditional field oxide isolation techniques. In transistors formed using shallow-trench isolation techniques, the top surface of the silicon dioxide at the edges of the trenches can lie below the level of the bottom of the source/drain implants in the active transistor regions. The polysilicon gates formed over the gate oxides of the transistors follow the contours formed by the lowered edges of the silicon dioxide used to fill the trenches and thus can also extend vertically below the level of the bottom of the source/drain implants in the active transistor regions. Because there is no field channel-stop implant in the shallow-trench isolation structures, radiation-induced current leakage can occur at the edges of the source and drain regions where the polysilicon transistor gate extends below the source and drain implants.

Attempts have been made to correct this problem by modifying the geometries of the silicon and silicon dioxide interface at the trench edges. These attempts have met with varying degrees of success.

### SUMMARY

A shallow-trench isolation transistor according to the present invention includes a sidewall channel-stop implant around the side and bottom walls of the trench. This implant surrounds the transistor and extends below the level of the source and drain implants in the active transistor region and significantly lowers the radiation-induced leakage currents that would otherwise exist in the shallow-trench isolation transistor.

A method for fabricating a shallow-trench isolation transistor according to the present invention includes forming isolation trenches to define active regions in a silicon substrate; performing sidewall isolation impants on the side and bottom walls of the isolation trenches in the n-channel (p-well) areas only; depositing a dielectric isolation material in the isolation trenches; planarizing the top surface of the silicon substrate and the dielectric isolation material using CMP techniques; forming a gate oxide layer over the active regions in the silicon substrate; forming and defining gate regions over the gate oxide layer in the active regions in the silicon substrate; and forming source and drain regions in the active regions in the silicon substrate. The method of the present invention requires the use of one additional mask for sidewall implant in the n-channel (p-well) areas only.

Another exemplary method is disclosed. The method for fabricating a shallow-trench isolation transistor on a semi-conductor substrate includes forming a single isolation trench having a uniform cross section to define an active region in the silicon substrate. The method includes performing sidewall isolation implants on the side and bottom walls of said isolation trench. The method includes depositing a dielectric isolation material in said isolation trench. The method includes planarizing the top surface of said silicon substrate and said dielectric isolation material. The method includes forming a gate oxide layer over said active region in said silicon substrate. The method includes forming and defining gate regions over said oxide layer in said active region in said silicon substrate. The method includes forming source and drain regions in the active region in the silicon substrate.

### BRIEF DESCRIPTION OF THE DRAWING FIGURES

FIG. 1 is a cross-sectional view of a conventional field oxide isolated MOS transistor.

FIG. 2 is a cross-sectional view of a conventional shallow-trench isolated MOS transistor.

FIG. 3 is a cross-sectional view of a shallow-trench isolated MOS transistor according to the present invention.

FIGS. 4A through 4C are cross-sectional views of a shallow-trench isolated MOS transistor showing the structure formed at different times during the progression of a fabrication process according to the method of the present invention.

FIG. 5 is a top view of a shallow-trench isolated MOS transistor according to the present invention.

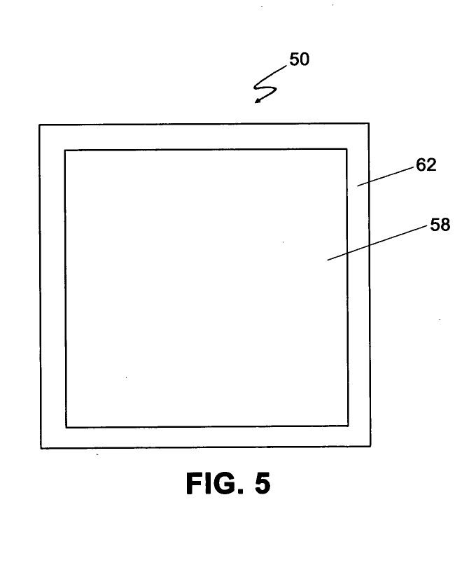

### DETAILED DESCRIPTION

Those of ordinary skill in the art will realize that the following description of the present invention is illustrative only and not in any way limiting. Other embodiments of the invention will readily suggest themselves to such skilled persons.

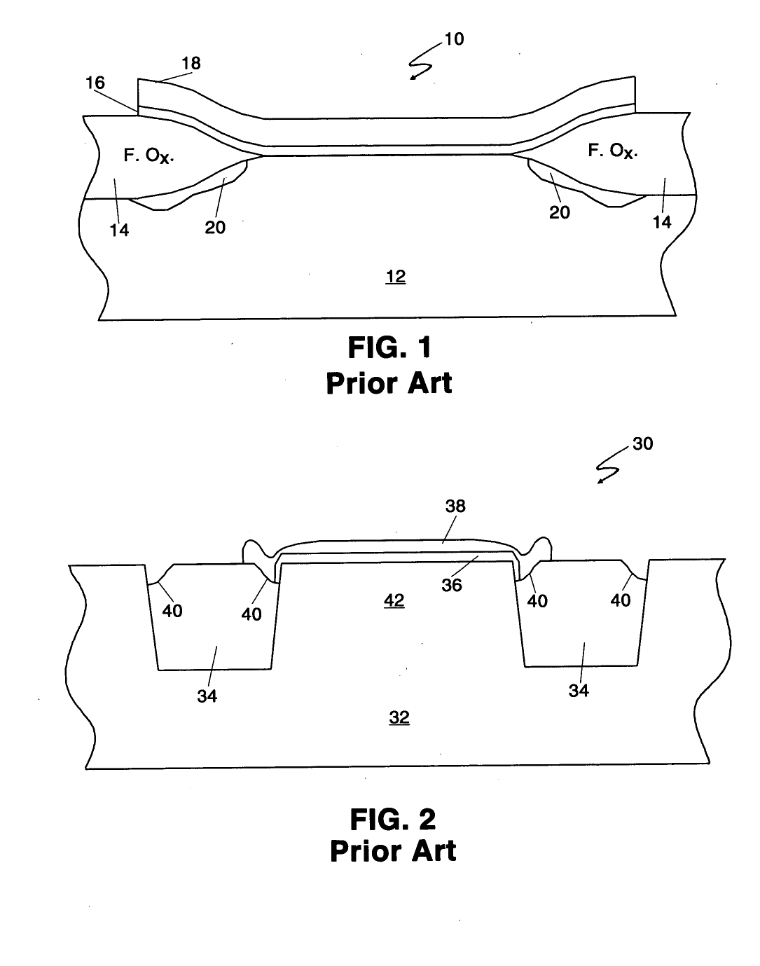

Referring first to FIG. 1, a cross-sectional view taken at the channel end of a conventional field oxide isolated MOS transistor 10 is shown. Transistor 10 is formed in silicon substrate 12 between two field oxide isolation regions 14 as is well known in the art. Gate oxide layer 16 insulates polysilicon gate 18 from the surface of substrate 12. Channel stop field implants 20, usually comprising a boron implant, underlie the birds beak edges of the field oxide regions.

The structure of FIG. 1 is well known in the art. It is known that MOS transistors such as the one illustrated in FIG. 1 exhibit increased radiation-induced leakage along channel ends at the birds beaks at the edges of the field oxide regions 14 caused by electron-hole pair charge buildup. It is known to reduce this radiation-induced current leakage by increasing the dose of the field channel-stop implant 14 under the birds beak edges of the field oxide isolation regions 14. Typically, field channel-stop implant doses may be increased from about 6e13 atoms/cm² up to about 1.2e14 atoms/cm².

As previously noted, while increasing the field channel-stop implant dose is known to decrease this radiation-induced current leakage, the increased field channel-stop implant dose has the unwanted effect of decreasing the junction breakdown voltage of the MOS transistor 10. The need to avoid unwanted lowering of the junction breakdown of the MOS transistor 10 limits the use of increased field channel-stop implant dose as a means of decreasing the radiation-induced current leakage in MOS transistors.

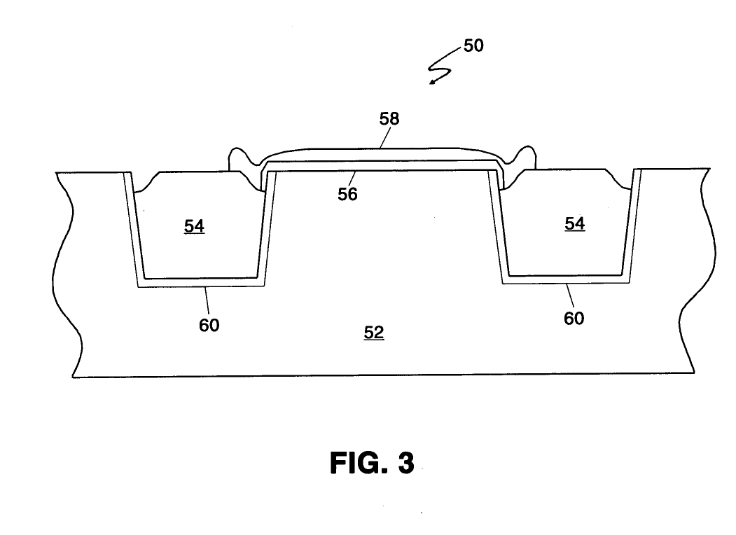

Referring now to FIG. 2, a cross-sectional view taken at the channel end of a conventional shallow-trench isolated MOS transistor 30 is shown. Transistor 30 is formed in silicon substrate 32 surrounded by a shallow trench isolation structure filled with deposited silicon dioxide 34 as is well known in the art. Gate oxide layer 36 insulates polysilicon gate 38 from the surface of substrate 32. Unlike transistor 10 of FIG. 1, no channel-stop field implants are employed.

In transistors 32 formed using shallow-trench isolation techniques, edges 40 of the top surface of the silicon dioxide regions 34 at the edges of the trenches can lie below the level of the bottom of the source/drain implants (not shown) in the active transistor regions 42. The polysilicon gates 38 formed over the gate oxides 36 of the transistors 32 follow the contours formed by the lowered top surfaces 40 of the silicon dioxide regions 34 used to fill the trenches and thus can also extend vertically below the level of the bottom of the source/drain implants in the active transistor regions 42. Because there is no field channel-stop implant in the gate edge region of conventional shallow-trench isolation structures, radiation-induced current leakage can occur at the edges of the source and drain regions where the polysilicon gate 38 of MOS transistor 32 extends below the source and drain implants.

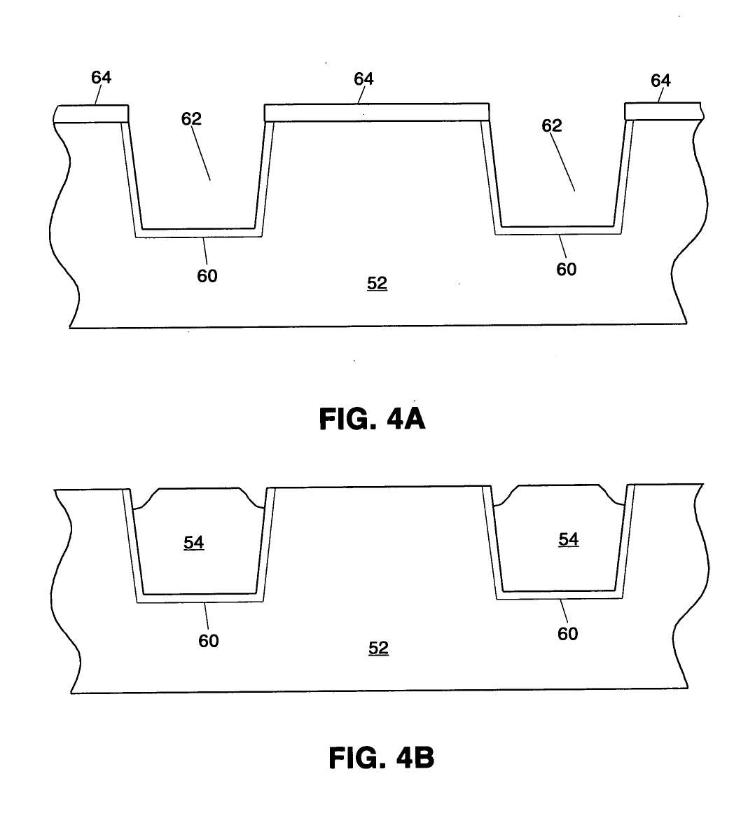

Referring now to FIG. 3, a cross-sectional view of a shallow-trench isolated MOS transistor 50 illustrates the features of the present invention. Shallow-trench isolated MOS transistor 50 is formed in silicon substrate 52 and is surrounded by a shallow portion, shown in FIG. 3, of an annular shallow trench isolation structure filled with deposited silicon dioxide 54 as in the prior-art shallow-trench isolated MOS transistor of FIG. 2. Gate oxide layer 56 insulates polysilicon gate 58 from the surface of substrate 25 illustrates a top view of transistor 50 in which trench 50 has a front portion, rear portion, and side portions which surround the active region of transistor 50.

Unlike the prior-art shallow-trench isolated MOS transistor of FIG. 2, a sidewall implant 60 is formed in the walls of the isolation trenches prior to the deposition of the oxide fill regions 54. The implant is performed at an angle so that it penetrates the sidewalls of the trenches. The substrate may be rotated or other techniques may be employed to assure implanting all four of the sidewalls shown in FIG. 3 as well as implanting on all four sidewalls of the front and rear portions of the trench not shown in FIG. 3.

As will be appreciated by persons of ordinary skill in the art, different species will be used for the sidewall implant 60 depending on whether N-Channel or P-Channel MOS transistors are being formed. For example, to form N-Channel MOS transistors according to the present invention, boron may be implanted at a dose of about 2.0e12. P-Channel MOS transistors do not need the sidewall trench implant according to the present invention.

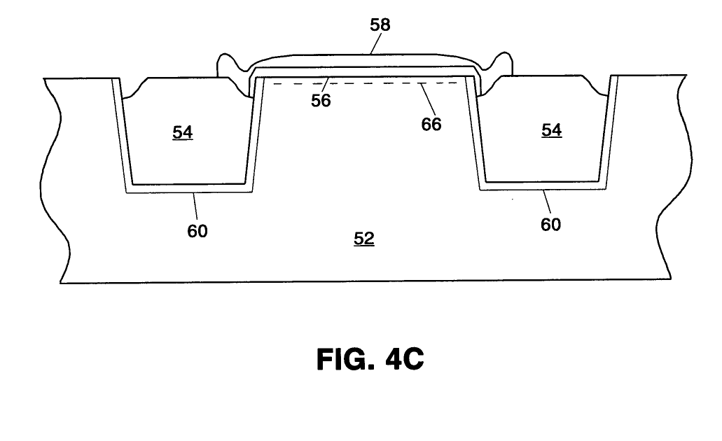

Turning now to FIGS. 4A through 4C, a method for fabricating shallow-trench isolated MOS transistors according to the present invention is illustrated. FIGS. 4A through 4C are cross-sectional views of a shallow-trench isolated MOS transistor showing the structure formed at different times during the progression of a fabrication process according to the method of the present invention. One skilled in the art will recognize that the shallow isolation trench 62 completely surrounds transistor 50. However, to better describe the invention, FIGS. 4A to 4C only illustrate cross sections showing two sides of trench surrounding transistor 50. Structures in FIGS. 4A through 4C corresponding to structures in FIG. 3 will be given the same reference numerals as seen in FIG. 3.

Referring now to FIG. 4A, substrate 52 is shown after formation of annular isolation trench 62. As will be appreciated by persons of ordinary skill in the art, isolation trench 62 is formed using conventional masking and etching techniques to a depth of about 400 nm, after which the mask layer is removed using conventional semiconductor processing techniques.

As shown in FIG. 1, sidewall implants 60 are formed in the side and bottom walls of isolation trench 62. As will be appreciated by persons of ordinary skill in the art, sidewall implants 60 may be formed using an angled ion-implant process during which the substrate 52 may be rotated as known in the art to assure coverage of all of the sidewalls of the isolation trench 62. FIG. 4A shows the structure existing after the performance of the sidewall implant step for one type of transistor before removal of implant mask layer 64.

In accordance with the present invention, sidewall implants for isolation of N-Channel MOS transistors according to the present invention may be performed by, for example, implanting boron at a concentration of about 2.0e12 at an angle of about 25°.

Referring now to FIG. 4B, implant mask layer 64 has been removed. Silicon dioxide regions 54 have been formed in annular isolation trench 62 using conventional CVD or PECVD techniques and the surfaces of silicon dioxide regions 54 and the top surface of substrate 52 have been planarized using conventional CMP techniques. Note that, as an artifact of the planarizing process and oxide etching steps, the edges of the top surface of silicon dioxide regions 54 lie below the edges of isolation trench 62.

Referring now to FIG. 4C, gate oxide layer 56 and polysilicon gate layer 58 have been formed and defined using conventional photolithographic and semiconductor processing techniques. Source and drain regions (outside of the plane of the cross-section of FIG. 4C and therefore shown as dashed lines 66) are implanted using the edges of the gate 58 as a mask in a conventional self-aligned gate process sequence. Note that the polysilicon gate regions adjacent to the edges of the isolation trench 62 lie below the level of the source and drain implants.

Persons of ordinary skill in the art will understand that, after performing the steps illustrated in FIGS. 4A through 4C, other conventional and well known processing steps, such as passivation and contact formation (not shown), will need to be performed top complete the integrated circuit.

An alternate technique to perform the function of the present invention involves performing an additional implant in the channel region at the time of the Vt implant in place of the trench sidewall implant in order to help negate leakage at the channel edges. According to this aspect of the present invention, a boron implant of between about 1.0e12 to about 1.5e12, preferably about 1.2e12, is made at an energy of between about 50 to about 100 keV, preferably about 80 keV. This implant is performed at the time of the Vt threshold adjusting implant prior to formation of the polysilicon gate.

While embodiments and applications of this invention have been shown and described, it would be apparent to those skilled in the art that many more modifications than mentioned above are possible without departing from the inventive concepts herein. The invention, therefore, is not to be restricted except in the spirit of the appended claims.

1. A method for fabricating a shallow-trench isolation transistor on a semi-conductor substrate including:
forming an isolation trench having a uniform cross section to define an enclosed active region in the silicon substrate;
performing sidewall isolation implants on the side and bottom walls of said isolation trench;
depositing a dielectric isolation material in said isolation trench;
planarizing the top surface of said silicon substrate and said dielectric isolation material;
forming a gate oxide layer over said active region in said silicon substrate;
forming and defining gate regions over said oxide layer in said active region in said silicon substrate; and
forming source and drain regions in the active region in the silicon substrate.

2. The method of claim 1 wherein performing said sidewall implants comprises implanting n-type impurities.

3. The method of claim 1 wherein implanting n-type impurities comprises implanting boron.

4. The method of claim 1 wherein implanting n-type impurities comprises implanting boron to a concentration of about 2e12.

5. The method of claim 1 wherein performing said sidewall implants comprises performing said sidewall implants at an angle.

6. The method of claim 5 wherein performing said sidewall implants at an angle comprises performing said sidewall implants at an angle of about 25°.
